(19) United States
(12) Patent Application Publication
(10) Pub. No.: US 2021/0296585 A1
(43) Pub. Date: Sep. 23, 2021

(54) SWITCHING DEVICE

(71) Applicant: Kioxia Corporation, Tokyo (JP)

(72) Inventors: Tadaomi DAIBOU, Yokkaichi Mie (JP); Hiroki KAWAI, Inazawa Aichi (JP); Katsuyoshi KOMATSU, Yokkaichi Mie (JP); Weidong LI, Yokkaichi Mie (JP); Shogo ITAI, Kawasaki Kanagawa (JP); Kouji MATSUO, Ama Aichi (JP)

(73) Assignee: Kioxia Corporation, Tokyo (JP)

(21) Appl. No.: 17/019,664

(22) Filed: Sep. 14, 2020

(30) Foreign Application Priority Data
Mar. 18, 2020 (JP) 2020-047243

(51) Int. Cl. H01L 45/00

(52) U.S. Cl. CPC H01L 45/145; H01L 27/15; H01L 45/146; H01L 45/147

(57) ABSTRACT

A switching device in an embodiment includes: a first electrode; a second electrode, and a switching layer disposed between the first electrode and the second electrode. The switching layer is made of a material containing hafnium nitride. Otherwise, the switching layer is made of a material containing bismuth and at least one selected from the group consisting of silicon oxide, aluminum oxide, zirconium oxide, and gallium oxide, or a material containing at least one selected from the group consisting of bismuth oxide, bismuth nitride, bismuth boride, and bismuth sulfide.

### CROSS REFERENCE TO RELATED APPLICATIONS

This application is based upon and claims the benefit of priority from Japanese Patent Application No. 2020-047243, filed on Mar. 18, 2020; the entire contents of which are incorporated herein by reference.

### FIELD

Embodiments disclosed herein generally relate to a switching device.

### BACKGROUND

A resistance change device having a switching layer, a resistance change layer as a nonvolatile memory layer, and the like is used in a semiconductor memory device. In such a resistance change device, a switching device having a switching layer is used to switch current on/off to the resistance change layer or the like. There is a need for a switching layer and a switching device using the switching layer reducing cost and improving switching properties.

### BRIEF DESCRIPTION OF THE DRAWINGS

FIG. 1 is a cross-sectional diagram illustrating a basic constitution of a switching device according to an embodiment.

FIG. 2 is a cross-sectional diagram illustrating a basic constitution of a resistance change device using the switching device according to the embodiment.

FIG. 3 is a perspective diagram illustrating the resistance change device illustrated in FIG. 2.

FIG. 4 is a diagram illustrating an I-V curve of an HfN layer as a switching layer of a switching device according to a first embodiment.

FIG. 5 is a diagram illustrating an I-V curve of an HfZrN layer as the switching layer of the switching device according to the first embodiment.

FIG. 6 is a diagram illustrating an example of a state density of Bi—Si—O.

FIG. 7 is a diagram illustrating an I-V curve of a Bi—Si—O layer as a switching layer of a switching device according to a second embodiment.

FIG. 8 is a diagram illustrating an I-V curve of a Bi—Al—O layer as the switching layer of the switching device according to the second embodiment.

FIG. 9A to FIG. 9D are diagrams each illustrating a Bi composition dependency of the I-V curve at the Bi—Si—O layer as the switching layer of the switching device according to the second embodiment.

FIG. 10 is a diagram illustrating an I-V curve of a BiO layer as the switching layer of the switching device according to the second embodiment.

FIG. 11 is a diagram illustrating an I-V curve of a BiN—Al—O layer as the switching layer of the switching device according to the second embodiment.

### DETAILED DESCRIPTION

Hereinafter, switching devices according to embodiments are explained with reference to the drawings. In embodiments, substantially the same components are denoted by the same reference signs, and a description thereof may be sometimes omitted. The drawings are schematic, and the relation between thicknesses and plane dimensions, ratios of the thicknesses of respective parts, and the like may sometimes differ from actual ones.

### First Embodiment

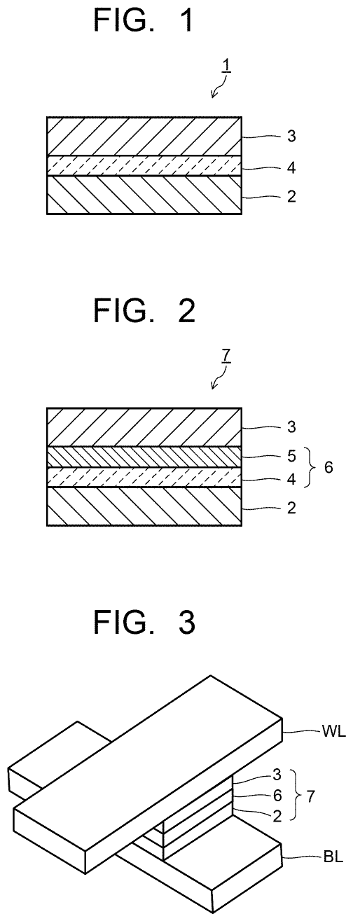

FIG. 1 is a cross-sectional diagram illustrating a basic constitution of a switching device 1 according to a first embodiment. The switching device 1 illustrated in FIG. 1 includes a first electrode 2, a second electrode 3, and a switching layer 4 disposed between the first electrode 2 and the second electrode 3. The switching layer 4 has a function of switching current flowing between the first electrode 2 and the second electrode 3 on or off. The switching layer 4 is in an off state with a high resistance value when a voltage of less than a threshold value (Vth) is applied and has electric properties that cause rapid transition from the off state with the high resistance value to an on state with a low resistance value when a voltage of the threshold value (Vth) or more is applied from the off state.

When the voltage applied to the switching layer 4 is lower than the threshold value (Vth), the switching layer 4 functions as an insulator and interrupts current flowing through a functional layer, such as a resistance change layer added to the switching layer 4, bringing the functional layer into the off state. When the voltage applied to the switching layer 4 exceeds the threshold value (Vth), a resistance value of the switching layer 4 drops steeply, and the switching layer 4 functions as a conductor, allowing the current to flow through the switching layer 4 to the functional layer. The switching device 1 with the switching layer 4 is applied to on/off control of the current to the functional layer in various electronic devices, for example.

The switching device 1 illustrated in FIG. 1 is applied to, for example, a resistance change device 7 in which a stacked film 6 of the switching layer 4 and a resistance change layer 5 functioning as a nonvolatile memory layer is disposed between the first electrode 2 and the second electrode 3, as illustrated in FIG. 2. The stacked film 6 in the resistance change device 7 is not limited to a structure in which the switching layer 4 and the resistance change layer 5 are directly stacked, but may also be a structure in which other layers such as an intermediate layer or an additional layer are interposed between the switching layer 4 and the resistance change layer 5, or a structure in which an intermediate layer or an additional layer is interposed between the first electrode 2 and the switching layer 4 or between the resistance change layer 5 and the second electrode 3. The resistance change device 7 is disposed at an intersection of a bit line BL and a word line WL to function as a memory cell, as illustrated in FIG. 3, for example. Although FIG. 3 illustrates only the intersection of one bit line BL and one word line WL, a semiconductor memory device is actually formed by disposing the resistance change device 7 as the memory cell at each intersection of a number of bit lines BL and word lines WL. A mode is also possible to have a second resistance change element and a second bit line BL further stacked on the word line WL. That is, a structure in which the word line WL and the bit line BL are alternately stacked and the resistance change element is disposed at a point where the word line WL and the bit line BL intersect, and the structure with the stacking number of one layer or more is also possible.

A memory layer in a publicly-known resistance change memory can be used for the resistance change layer 5. A resistive random access memory (ReRAM), a phase change memory (PCM), a magnetoresistive random access memory (MRAM), and so on are known as the resistance change memories. The memory layers of these various resistance change memories are used as the resistance change layer 5. The resistance change layer 5 is not limited to a single-layer structure, but may also be a multilayer film necessary for each memory to function. The switching device 1 is used for switching of various electronic devices without being limited to the resistance change device 7.

In the resistance change device 7 illustrated in FIG. 2 and FIG. 3, the switching layer (selector layer) 4 is electrically connected to the resistance change layer 5 and has the function of switching the current to the resistance change layer 5 on or off. When the voltage applied to the switching layer 4 is lower than the threshold value (Vth), the switching layer 4 functions as the insulator and interrupts the current flowing to the resistance change layer 5, bringing the resistance change layer 5 into the off state. When the voltage applied to the switching layer 4 exceeds the threshold value (Vth), the resistance value of the switching layer 4 drops steeply and the switching layer 4 functions as the conductor, causing the current to flow through the switching layer 4 to the resistance change layer 5, allowing for write or read operation of the resistance change layer 5. The switching device 1 has a function of switching the resistance change layer 5 as the memory layer on or off in the resistance change device 7, which functions as the resistance change memory.

In the switching device 1 of the first embodiment described above, the switching layer 4 contains at least hafnium nitride (HfN). The representation of HfN does not express a ratio of Hf and N, and expresses that Hf and N are contained. The representation of other compounds is similar, and AB or A-B expresses that A and B are contained, and ABC or A-B-C expresses that A, B and C are contained. For example, hafnium nitride with a composition represented by Hf₃N₄ has a band gap of approximately 1.84 eV. An example of a mechanism for switching properties is thought to be derived from an electrical conduction mechanism through localized states in the band gap due to an amorphous structure. HfN can have the amorphous structure based on conditions of film-formation and the like. The switching layer 4 containing hafnium nitride (HfN) thereby exhibits a property of transitioning between the high resistance state and the low resistance state (switching properties) based on the threshold value (Vth) of the voltage.

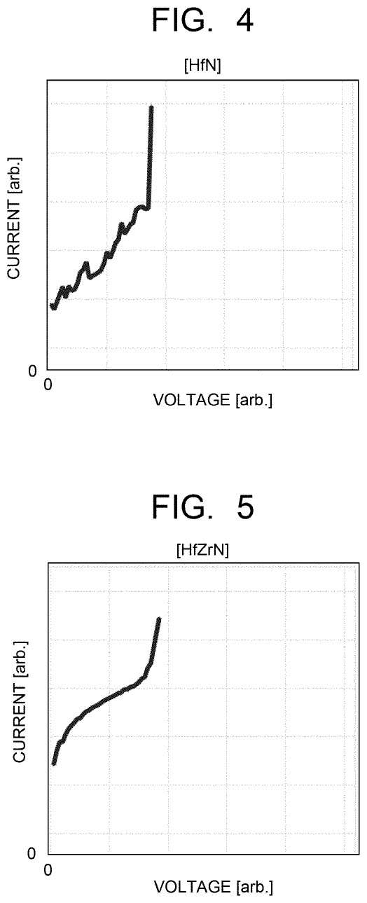

FIG. 4 illustrates change in current values (I-V curve) when voltage is applied to an HfN layer with a film thickness of 10 nm. The HfN layer was film-formed by sputtering a metal hafnium target in an N₂ gas atmosphere. In FIG. 4, units on vertical and horizontal axes are both arbitrary units, and the vertical axis is a logarithmic scale. The same is true for the other drawings illustrating the I-V curves shown below. As illustrated in FIG. 4, when the voltage is applied to the HfN layer, current increases steeply when a certain voltage is applied, and switching behavior is observed. The switching device 1 can be therefore achieved by using the switching layer 4 made of the HfN layer.

The switching layer 4 containing hafnium nitride (HfN) may further contain at least one selected from a group consisting of yttrium nitride (YN), zirconium nitride (ZrN), titanium nitride (TiN), and scandium nitride (ScN). The switching layer 4 may contain at least one element (hereinafter, referred to as element M) selected from the group consisting of yttrium (Y), zirconium (Zr), titanium (Ti), and scandium (Sc). By adding the nitride of the element M (MN) to hafnium nitride, various switching properties can be controlled. In other words, amorphization of the switching layer 4 containing HfN can be promoted by adding nitride of group 4 Zr or Ti, which is a same family of Hf, or nitride of group 3 Sc to HfN to multiply elements that form nitrides. The switching layer 4 made of such materials also exhibits the switching properties. The element composing the nitride may be the meat element.

Concrete constituent materials of the switching layer 4 made of a material containing HfN and at least one selected from the group consisting of YN, ZrN, TiN, and ScN (hereinafter, also referred to as Hf-containing composite nitride) include a mixture of HfN and MN such as HfYN, HfZrN, HfTiN, HfScN, HfZrTiN, HfZrScN, HfTiScN, HfZrTiScN, and are not particularly limited. The switching layer 4 may have a stack which a layer containing HfN and a layer containing MN are stacked, and examples include, for example, HfN/YN, HfN/ZrN, HfN/TiN, HfN/ScN, HfN/YN/TiN, HfN/ZrN/TiN, HfN/ZrN/ScN, HfN/TiN/ScN, HfN/ZrN/TiN/ScN, and the like, and are not particularly limited. The switching layer 4 may also be a stack of the Hf-containing composite nitrides, and examples include, for example, HfYN/YN, HfZrN/ZrN, HfZrNiTiN, HfZrN/ScN, HfN/ZrN/TiN, HfN/ZrN/ScN, HfZrN/TiZrN/ScN, HfN/ZrN/TiN/ScZrN, and so on, and are not particularly limited. FIG. 5 illustrates an I-V curve of an HfZrN (a concrete composition is (Hf₇₅Zr₂₅)N (numerical values are each atom %)) layer with a film thickness of 10 nm. As illustrated in FIG. 5, when voltage is applied to HfZrN, current increases steeply when a certain voltage is applied, and switching behavior is observed. Accordingly, the switching device 1 can also be achieved by using the switching layer 4 made of the HfZrN layer. A similar switching behavior can be obtained in the case of Hf and nitride containing at least one of the element M selected from Y, Zr, Ti, and Sc.

It is clear from the comparison between FIG. 4 and FIG. 5 that the I-V curve can be modulated by adding ZrN to HfN. That is, according to the switching layer 4 made of the composite nitride where ZrN is added to HfN, it is possible to control an operating voltage or the like at which the switching layer 4 made of HfN switches. Thus, the switching behavior in accordance with an electronic device to which the switching device 1 is applied, for example, the switching behavior based on a controlled operating voltage, can be obtained by adjusting the composition of the material (Hf-containing composite nitride) making up the switching layer 4 in response to the electronic device to which the switching device 1 is applied.

The switching layer 4 made of HfN or the Hf-containing composite nitride described above may further contain at least one element (hereinafter, referred to as element SM) selected from the group consisting of boron (B), carbon (C), and phosphorus (P). These elements (B, C, and P) are all elements that promote amorphization. Stability or the like of the switching behavior by the switching layer 4 can be therefore increased. At least one element SM selected from B, C, and P may be added to either HfN or the Hf-containing composite nitride. Further, aluminum nitride (AlN), silicon nitride (SiN), and the like may be contained in some cases to adjust electrical conductivity and the like of HfN and the Hf-containing composite nitride.

In the above Hf-containing composite nitride, though a composition ratio of the metallic elements (Hf, Y, Zr, Ti, and Sc) is not particularly limited, a ratio of Hf to a total metallic element is preferably set to 1 atom % or more to stably obtain the switching properties based on HfN. A total ratio of the element M (Y, Zr, Ti, Sc) to the total metallic element is preferably 1 atom % or more and 50 atom % or less to promote amorphization and the like based on the metallic elements (M:Y, Zr, Ti, Sc) other than Hf. In the metallic elements in the Hf-containing composite nitride, the metallic element other than the element M is basically Hf. The metallic elements in the Hf-containing composite nitride preferably contain 1 atom % or more and 50 atom % or less of the element M and balancing Hf. Further, when HfN and the Hf-containing composite nitride contain the element SM (B, C, and P), a ratio of the element SM to the total constituent elements is preferably 50 atom % or less to maintain the properties and modes as nitride.

The switching layer 4 containing at least HfN as described above preferably has a microcrystal or amorphous structure to homogenize film properties and the like. Further, in obtaining the switching properties, the HfN layer and the HfMN layer making up the switching layer 4 preferably have the amorphous structure, as described above. In obtaining the amorphous structure, the HfN layer and the HfMN layer may contain at least one selected from the group consisting of B, C, and P to promote or stabilize the amorphization. A film thickness of the switching layer 4 is preferably 5 nm or more and 30 nm or less.

For forming the switching layer 4 made of HfN or HfMN, a sputtering method or a vapor-deposition method can be applied. The switching layer 4 made of HfN can be formed using, for example, an HfN target whose composition has been adjusted. Otherwise, an HfN film can be formed by exposing an Hf metal target to a nitrogen atmosphere or nitrogen plasma during or after film-formation. When the switching layer 4 made of HfMN is used, the film can be formed by sputtering or vapor-depositing a nitride (MN) target of at least one metallic element M selected from Y, Zr, Ti, and Sc with the HfN target. Otherwise, an HfMN film can be formed using a HfMN target whose composition has been adjusted. The HfMN film whose composition has been adjusted can also be obtained by alternately stacking the HfN film and the MN film.

Further, when the elements SM (B, C, and P) are added to HfN or HfMN, the HfN film or the HfMN film containing the elements SM can be obtained by using a target with a desired amount of the elements SM. The constituent materials of the switching layer 4 thus obtained include HfNB, HfYNB, HfZrNB, HfTiNB, HfScNB, HfYZrNB, HfZrTiNB, HfZrScNB, HfTiScNB, HfZrTiScNB, HfNC, HfZrNC, HfTiNC, HfScNC, HfZrTiNC, HfZrScNC, HfTiScNC, HfZrTiScNC, HfNP, HfZrNP, HfTiNP, HfScNP, HfZrTiNP, HfZrScNP, HfTiScNP, HfZrTiScNP, HfNBC, HfYNBC, HfZrNBC, HfTiNBC, HfScNBC, HfZrTiNBC, HfZrScNBC, HfTiScNBC, HfZrTiScNBC, HfNBP, HfYNBP, HfZrNBP, HfTiNBP, HfScNBP, HfZrTiNBP, HfZrScNBP, HfTiScNBP, HfZrTiScNBP, HfNCP, HfYNCP, HfZrNCP, HfTiNCP, HfScNCP, HfYTiNCP, HfZrTiNCP, HfZrScNCP, HfTiScNCP, HfYTiScNCP, HfZrTiScNCP, HfNBCP, HfZrNBCP, and HfTiNBCP, HfScNBCP, HfZrTiNBCP, HfZrScNBCP, HfTiScNBCP, or HfYZrTiScNBCP.

Constituent materials of the electrodes 2 and 3 in direct or indirect contact with the switching layer 4 containing at least HfN are not particularly limited, but include, for example, a TiN film, a TiN/Ti stacked film, a C/TiN/Ti stacked film, a W film, a C/W/TiN stacked film, and the like. In addition to the above, metal electrodes made of a W alloy, Cu, a Cu alloy, Al, an Al alloy, and the like used as electrodes in various semiconductor elements may also be applied to the electrodes 2 and 3.

In the switching device 1 of the first embodiment, the switching layer 4 is made of HfN, HfMN, or a material with the elements SM added to HfN or HfMN, and the switching layer 4 as stated above exhibits the switching properties which make a transition between the high resistance state and the low resistance state based on the threshold value (Vth) of the voltage, as mentioned above. Accordingly, it is possible to provide the switching device 1 having good properties and cost reduction without using selenium (Se) or tellurium (Te), which is the chalcogen element, as the main component.

### Second Embodiment

A switching device in a second embodiment includes the first electrode 2, the second electrode 3, and the switching layer 4 disposed between the first electrode 2 and the second electrode 3 as same as the switching device 1 in the first embodiment illustrated in FIG. 1. As mentioned above, the switching layer 4 has the function of switching the current flowing between the first electrode 2 and the second electrode 3 on or off. The switching layer 4 is in the off state with the high resistance value when the voltage of less than the threshold value (Vth) is applied, and has electric properties that cause rapid transition from the off state with the high resistance value to the on state with the low resistance value when the voltage of the threshold value (Vth) or more is applied from the off state.

The switching device 1 in the second embodiment is applied to on/off control of the current to functional layers in various electronic devices as same as the switching device 1 in the first embodiment. Concretely, the switching device 1 in the second embodiment is applied to the resistance change device 7 in which the stacked film 6 of the switching layer 4 and the resistance change layer 5 functioning as the nonvolatile memory layer is disposed between the first electrode 2 and the second electrode 3, as illustrated in FIG. 2 and FIG. 3. The resistance change device 7 is disposed at each intersection of a number of bit lines BL and word lines WL as a memory cell, as illustrated in FIG. 3, and a semiconductor memory device is thereby formed. A memory layer in a publicly-known resistance change memory is used as the resistance change layer 5 as same as the first embodiment.

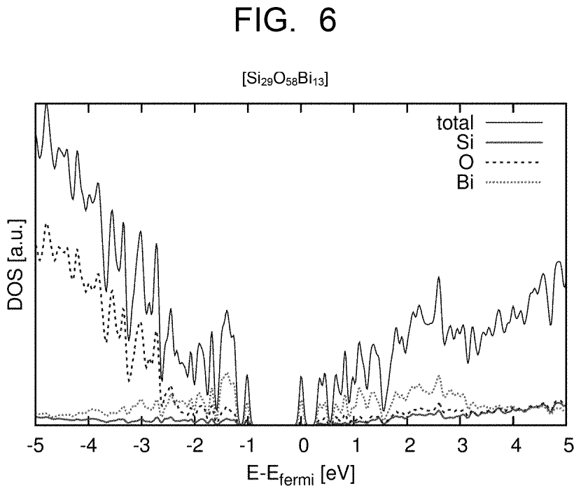

In the switching device 1 of the second embodiment, the switching layer 4 is made of a material containing bismuth (Bi) and at least one selected from the group consisting of silicon oxide (SiO), aluminum oxide (AlO), zirconium oxide (ZrO), and gallium oxide (GaO) (hereinafter, also referred to as Bi-based composite material). The oxide of at least one element selected from the group consisting of Si, Al, Zr, and Ga (hereinafter, also referred to as element A) (oxide is AO) is an insulator. According to the material in which semi-metallic Bi is added to the oxide (AO) (hereinafter, also referred to as Bi-AO material), it is possible to obtain semiconducting conductivity and a band gap as large as that of a compound containing the chalcogen element. A state density of Si₂₉O₅₈Bi₁₃ calculated by a first-principles calculation is illustrated in FIG. 6 as an example. It can be seen that the band gap value is close to that of the compound containing the chalcogen element. As mentioned above, the switching properties are thought to be derived from the electrical conduction mechanism through localized states in the band gap due to the amorphous structure, as an example. The switching layer 4 made of the Bi-AO material thereby exhibits the property of transitioning between the high resistance state and the low resistance state (switching properties) based on the threshold value (Vth) of the voltage.

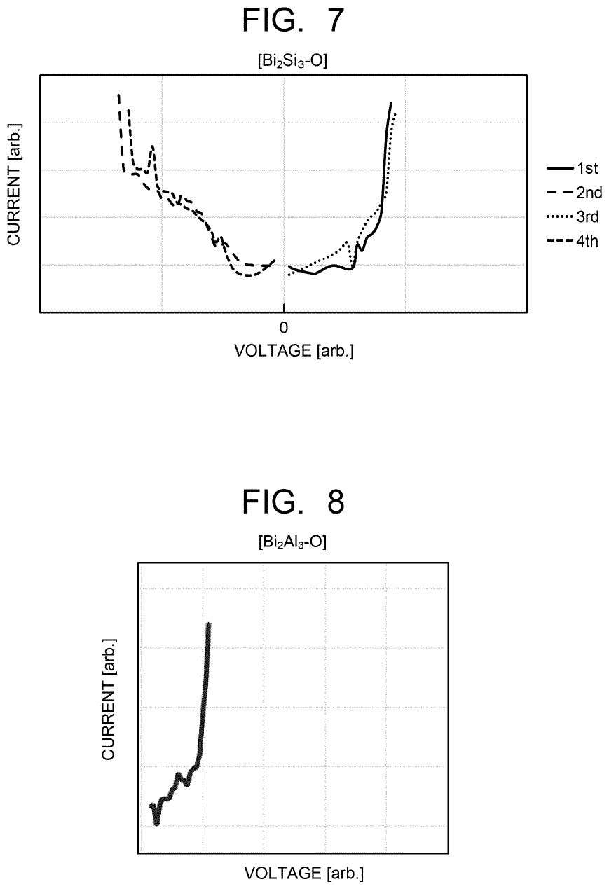

FIG. 7 illustrates change in current values (I-V curve) when voltage is applied to a Bi—Si—O (a concrete composition: a molar ratio of Bi to Si is 2:3) layer with a film thickness of 10 nm on positive and negative bias sides. The Bi—Si—O layer was film-formed by sputtering using a composite target of Bi and Si oxide. As illustrated in FIG. 7, when the voltage is applied to the Bi—Si—O layer, current increases steeply at a certain voltage in both the positive and negative bias sides, and the switching behavior is observed. The switching device 1 can be therefore achieved by using the switching layer 4 made of the Bi—Si—O layer.

In the switching device 1 of the second embodiment, a Bi—Al—O layer, a Bi—Zr—O layer, and a Bi—Ga—O layer can be used instead of the Bi—Si—O layer. The Bi—Al—O layer, the Bi—Zr—O layer, and the Bi—Ga—O layer also exhibit the same properties as the Bi—Si—O layer and thus can function as the switching layer 4. FIG. 8 illustrates change in current values (I-V curve) when voltage is applied to the Bi—Al—O (a concrete composition: a molar ratio of Bi to Al is 2:3) layer with a film thickness of 10 nm. As illustrated in FIG. 8, when the voltage is applied to the Bi—Al—O layer, current increases steeply at a certain voltage, and the switching behavior is observed. The switching device 1 can be therefore achieved by using the switching layer 4 made of the Bi—Al—O layer. The same is true for the Bi—Zr—O layer and the Bi—Ga—O layer.

Further, the metal oxide to which Bi is added is not limited to the aforementioned single oxide of the element A, but may also be a composite oxide of at least two or more metallic elements selected from Si, Al, Zr, and Ga. Examples of concrete materials include binary metal oxides such as SiAlO, SiZrO, SiGaO, AlZrO, AlGaO, and ZrGaO, ternary metal oxides such as SiAlZrO, SiAlGaO, SiZrGaO, and AlZrGaO, and quaternary metal oxides such as SiAlZrGaO. Even when Bi is added to multi-component metal oxides as stated above, the switching device 1 exhibiting the switching properties can be achieved.

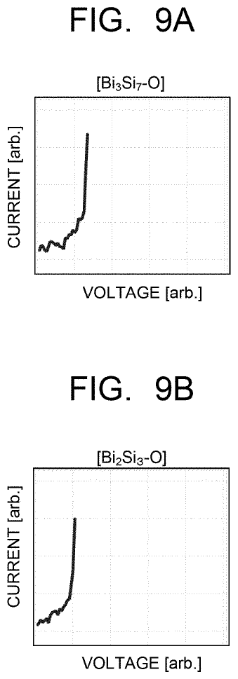

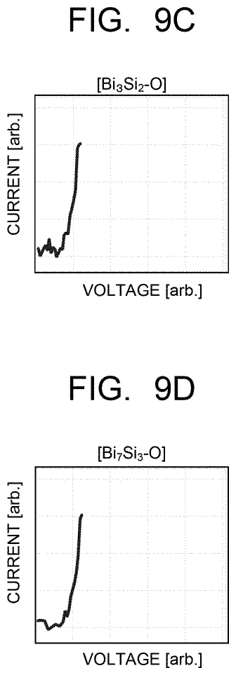

In the switching layer 4 made of the Bi-AO material described above, a composition ratio of Bi to AO is not particularly limited. FIG. 9A to FIG. 9D each illustrate an I-V curve for varying the ratio of Bi to Si oxide in the Bi—Si—O layer. FIG. 9A is the I-V curve with the concrete composition when a molar ratio of Bi to Si is 3:7, FIG. 9B is the I-V curve with the concrete composition when the molar ratio of Bi to Si is 2:3, FIG. 9C is the I-V curve with the concrete composition when the molar ratio of Bi to Si is 3:2, and FIG. 9D is the I-V curve with the concrete composition when the molar ratio of Bi to Si is 7:3. As illustrated in FIG. 9A to FIG. 9D, current increases steeply at a certain voltage in each of the Bi—Si—O layers with any compositions, and the switching behavior is observed. Thus, the Bi-AO material exhibits the switching properties at various composition ratios. When the Bi-AO material is used to make up the switching layer 4, the ratio of Bi in the Bi-AO material is preferably 20 mol % or more and less than 100 mol % with respect to the element A to stably obtain the switching properties.

In the switching device 1 of the second embodiment, at least one selected from the group consisting of bismuth oxide (BiO), bismuth nitride (BiN), bismuth boride (BiB), and bismuth sulfide (BiS) (hereinafter, also referred to as Bi compound) may be applied to the switching layer 4, instead of the above-mentioned Bi-AO material. For example, BiO with the composition represented by Bi₂O₃ has a band gap of approximately 2.6 eV. BiN has a band gap of approximately 1.2 eV. Further, an example of the mechanism for the switching properties may be derived from the electrical conduction mechanism through localized states in the band gap due to the amorphous structure. The above-mentioned Bi compounds can have the amorphous structure based on film formation conditions and the like. The switching layer 4 containing the Bi compound such as BiO, BiN, BiB, and BiS thereby exhibits the switching properties.

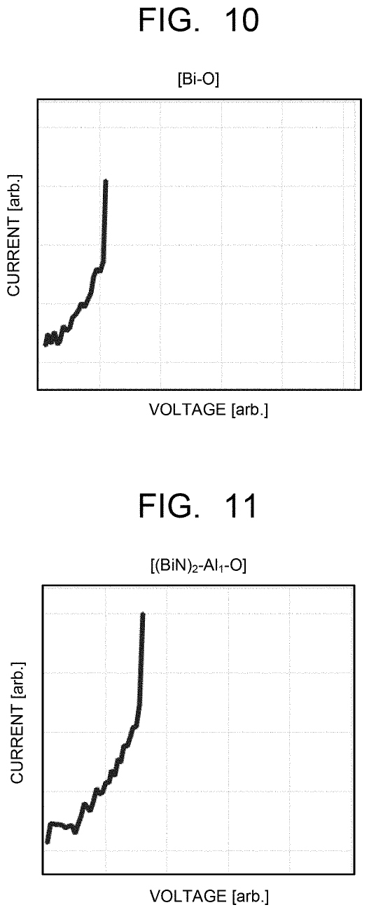

FIG. 10 illustrates change in current values (I-V curve) when voltage is applied to a Bi—O layer with a film thickness of 10 nm. As illustrated in FIG. 10, when the voltage is applied to the Bi—O layer, current increases steeply when a certain voltage is applied, and the switching behavior is observed. Such properties can be obtained not only in the Bi—O layer, but also in a Bi—N layer, a Bi—B layer, and a Bi—S layer. Thus, the switching device 1 can be achieved by using the switching layer 4 made of the Bi—O layer, the Bi—N layer, the Bi—B layer, or the Bi—S layer. The Bi compound making up the switching layer 4 may be a composite Bi compound such as Bi—O—N, Bi—O—B, Bi—O—S, Bi—O—N—B, and the like.

Further, at least one oxide (AO) selected from the group consisting of silicon oxide (SiO), aluminum oxide (AO), zirconium oxide (ZrO), and gallium oxide (GaO) may be added to the above-described Bi compound and applied to the constituent material of the switching layer 4. FIG. 11 illustrates change in current values (I-V curve) when voltage is applied to a BiN—Al—O (concrete composition: a molar ratio of BiN to Al is 2:1) layer with a film thickness of 10 nm. As illustrated in FIG. 11, when the voltage is applied to the BiN—Al—O layer, current increases steeply at a certain voltage, and the switching behavior is observed. Thus, the switching device 1 can be achieved by using the switching layer 4 made of the BiN—Al—O layer. The same is true for a Bi—O—Al layer, a Bi—B—Al—O layer, a Bi—S—Al—O layer, a BiO—Si layer, a Bi—N—Si—O layer, a Bi—B—Si—O layer, a Bi—S—Si—O layer, a Bi—O—Si—Al layer, a Bi—Si—Zr—O layer, and so on.

The switching layer 4 made of the Bi-AO materials, the Bi compounds, or the Bi compound-AO materials described above may further contain at least one element (element SM) selected from the group consisting of boron (B), carbon (C), and phosphorus (P). These element SM (B, C, and P) are all elements promoting amorphization, as mentioned above. The stability or the like of the switching behavior by the switching layer 4 can be therefore increased. The elements SM (B, C, P) may be added to any of the Bi-AO materials, the Bi compounds, and the Bi compound-AO materials. Further, aluminum nitride (AlN), silicon nitride (SiN), and the like may be contained in some cases to adjust the electrical conductivity and the like of the Bi-AO material, the Bi compound, or the Bi compound-AO material.

The switching layer 4 made of the Bi-AO material, the Bi compound, or the Bi compound-AO material as described above preferably has the microcrystal structure or the amorphous structure to homogenize the film properties. Further, in obtaining the switching properties, the Bi-AO material layer, the Bi compound layer, or the Bi compound-AO material layer making up the switching layer 4, as described above, preferably has the amorphous structure. In obtaining the amorphous structure, the Bi-AO material layer, the Bi compound layer, or the Bi compound-AO material layer may contain at least one element SM selected from the group consisting of B, C, and P to promote or stabilize the amorphization. The film thickness of the switching layer 4 is preferably 5 nm or more and 30 nm or less.

For example, the sputtering method or the vapor-deposition method can be applied to form the switching layer 4 made of the Bi-AO material layer, the Bi-compound layer, or the Bi compound-AO material layer. The switching layer 4 made of the Bi compound layer can be formed using, for example, a BiO target, a BiN target, a BiB target, a BiS target, or a composite target of these, whose composition has been adjusted. The switching layer 4 made of BiO or BiN can be obtained by exposing to an oxygen or nitrogen atmosphere during or after film-formation of the Bi film. The switching layer 4 made of the Bi-AO material layer and the Bi compound-AO material layer can be formed using composite targets whose compositions have been adjusted, respectively. Besides, a Bi-AO material film or a Bi compound-AO material film whose composition has been adjusted can be also obtained by alternately stacking the Bi film or the Bi-compound and the AO film. Further, a BiO-AO film can also be obtained by exposing to the oxygen atmosphere during or after film-formation of the Bi-A film.

Constituent materials of the electrodes 2 and 3 in direct or indirect contact with the switching layer 4 made of the Bi-AO material layer, the Bi compound layer, or the Bi compound-AO material layer are not particularly limited, but include a TiN film, a TiN/Ti stacked film, a C/TiN/Ti stacked film, a W film, a C/W/TiN stacked film, and the like. In addition to these, metal electrodes made of Cu, a Cu alloy, Al, an Al alloy, or the like, which are used as electrodes in various semiconductor elements, may also be applied to the electrodes 2 and 3.

In the switching device 1 of the second embodiment, the switching layer 4 is constituted by the Bi-AO material layer, the Bi-compound layer, or the Bi compound-AO material layer, or the material where the element SM (B, C, P) are added to the above materials as described above, and the switching layer 4 exhibits the switching properties that make a transition between the high resistance state and the low resistance state based on the threshold value (Vth) of the voltage as mentioned above. Accordingly, it is possible to provide the switching device 1 improving switching properties and having good switching properties and cost reduction.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A switching device, comprising:
a first electrode;
a second electrode, and
a switching layer disposed between the first electrode and the second electrode, wherein
the switching layer contains hafnium nitride.

2. The device according to claim 1, wherein
the switching layer further contains at least one selected from the group consisting of yttrium nitride, zirconium nitride, titanium nitride, and scandium nitride.

3. The device according to claim 1, wherein
the switching layer contains a mixture of hafnium nitride and at least one selected from the group consisting of yttrium nitride, zirconium nitride, titanium nitride, and scandium nitride.

4. The device according to claim 3, wherein
the switching layer has a composition regarding metal elements, containing 1 atom % or more and 50 atom % or less of at least one selected from the group consisting of yttrium, zirconium, titanium, and scandium and balancing hafnium.

5. The device according to claim 1, wherein
the switching layer has a stack which a first layer containing hafnium nitride and a second layer containing at least one selected from the group consisting of yttrium nitride, zirconium nitride, titanium nitride, and scandium nitride are stacked.

6. The device according to claim 1, wherein
the switching layer further contains at least one selected from the group consisting of boron, carbon, and phosphorus.

7. The device according to claim 6, wherein
the switching layer contains 50 atom % or less of at least one selected from the group consisting of boron, carbon, and phosphorus.

8. The device according to claim 1, wherein
the switching layer has an amorphous structure.

9. A switching device, comprising:
a first electrode;
a second electrode, and
a switching layer disposed between the first electrode and the second electrode, wherein
the switching layer contains bismuth and at least one selected from the group consisting of silicon oxide, aluminum oxide, zirconium oxide, and gallium oxide.

10. The device according to claim 9, wherein
the switching layer contains 20 atom % or more and less than 100 atom % of bismuth.

11. The device according to claim 9, wherein
the switching layer contains a mixture of bismuth and at least one selected from the group consisting of silicon oxide, aluminum oxide, zirconium oxide, and gallium oxide.

12. The device according to claim 9, wherein
the switching layer has a stack which a first layer containing bismuth and a second layer containing at least one selected from the group consisting of silicon oxide, aluminum oxide, zirconium oxide, and gallium oxide.

13. The device according to claim 9, wherein
the switching layer contains at least one selected from the group consisting of boron, carbon, and phosphorus.

14. The device according to claim 9, wherein
the switching layer has an amorphous structure.

15. A switching device, comprising:
a first electrode;
a second electrode, and
a switching layer disposed between the first electrode and the second electrode, wherein
the switching layer contains at least one selected from the group consisting of bismuth oxide, bismuth nitride, bismuth boride, and bismuth sulfide.

16. The device according to claim 15, wherein
the switching layer further contains at least one selected from the group consisting of silicon oxide, aluminum oxide, zirconium oxide, and gallium oxide.

17. The device according to claim 15, wherein
the switching layer further contains at least one selected from the group consisting of boron, carbon, and phosphorus.

18. The device according to claim 15, wherein
the switching layer has an amorphous structure.
